(19) United States
(12) Patent Application Publication
(10) Pub. No.: US 2009/0117683 A1
(43) Pub. Date: May 7, 2009

(54) Method of manufacturing single crystal substate and method of manufacturing solar cell using the same

(75) Inventor: Hyung Dong Kang, Gyeonggi-do (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD.

(21) Appl. No.: 12/155,156

(22) Filed: May 30, 2008

(30) Foreign Application Priority Data
Nov. 5, 2007 (KR) 10-2007-0112343

(51) Int. Cl. H01L 21/00; C30B 11/00

(52) U.S. Cl. 438/72; 117/81; 257/E21.029

(57) ABSTRACT

In accordance with the present invention, a method for manufacturing a single-crystal substrate comprising the steps of: preparing a square-shaped frame; pouring polycrystalline molten silicon into the prepared frame; cooling and crystallizing the molten silicon; and forming the single-crystal silicon substrate by transferring a heating element from one corner of the frame to another corner opposite the corner, thus simplifying the entire manufacturing process of the single-crystal substrate and reducing the material cost.

### CROSS-REFERENCE TO RELATED APPLICATIONS

This application claims the benefit of Korean Patent Application No. 10-2007-0112343 filed with the Korea Intellectual Property Office on Nov. 5, 2007, the disclosure of which is incorporated herein by reference.

### BACKGROUND OF THE INVENTION

1. Field of the Invention

The present invention relates to a method for manufacturing a single crystal substrate and a method for manufacturing a solar cell using the same; and, more particularly, to a method for manufacturing a single-crystal substrate for obtaining a single-crystal silicon substrate from polycrystalline molten silicon by pouring the molten silicon into a square-shaped frame, solidifying the molten silicon and transferring a heating element from one corner of the frame to another corner opposite the corner and a method for manufacturing a solar cell using the single-crystal substrate.

2. Description of the Related Art

A general principle of power generation of a solar cell is that when the light with proper energy is impinged on a single-crystal silicon or an amorphous silicon semiconductor layer, electrons and holes are generated by interaction between the impinged light and the semiconductor layer and in the case where there is an electric field by PN junction of the semiconductor layer, the electrons and the holes are diffused to an N-type semiconductor layer and a P-type semiconductor layer respectively, thus generating power by connecting both electrodes.

A small battery has been manufactured from the solar cell according to the above-mentioned principle of power generation and utilized as power source of portable small electronics and recently, various technical researches and developments have been made on characteristic improvement and low cost of the solar cell as technologies concerning electronics and semiconductor have been advanced remarkably.

Hereinafter, a method for manufacturing a single-crystal substrate will be described in detail with reference to the accompanying drawings.

FIG. 1 is a cross-section view showing a single-crystal silicon pulling apparatus in accordance with a conventional technology and FIG. 2 is a perspective view illustrating a cutting process of a single-crystal silicon in accordance with the conventional technology.

First of all, as shown in FIG. 1, the single-crystal silicon in accordance with the conventional technology is produced by the silicon pulling apparatus, wherein the silicon pulling apparatus has a water cooling metallic chamber 1, inside the center of the metallic chamber 1, there is coupled a crucible 2 made of a material which is not molten even at high temperature and the crucible holds polycrystalline molten silicon 7 used as a crystal raw material.

Further, on an upper part of the crucible 2, there is provided a seed chuck 5 to maintain single-crystals of the silicon 8 and the seed chuck is installed to a wire 6, whereby a seed crystal of the silicon 8 is rotated and pulled upward by rotating and pulling the wire 6.

In the conventional method for manufacturing the single-crystal silicon using the pulling apparatus, a high-purity polycrystalline raw material of the silicon is received in the crucible 2 and the high-purity polycrystalline raw material received therein is heated and molten by heating the crucible 2. At this time, because the melting point of the polycrystalline raw material is 1420° C., the polycrystalline raw material is molten entirely to become liquefied by heating at more than the temperature.

Then, after bringing a front end of a longitudinal crystal 4 into contact with the center of the surface of the molten silicon, when winding and pulling the wire 6, a silicon single-crystal 8 begins to be grown from the longitudinal crystal 4 and the wire 6 is pulled upward when the silicon single-crystal 8 with a predetermined size is completed.

When the wire 6 is pulled upward, the silicon single-crystal 8 is grown continuously about the seed chuck 5 with maintaining the size thereof constantly and formed in a long cylindrical shape.

As shown in FIG. 2, to make a wafer with the silicon single-crystal 8 manufactured by the conventional method respectively, a cutting process is performed using a cutter 9 capable of cutting a fine wire and a plurality of silicon single-crystal wafers 8a are manufactured by cutting the wafer with the cutter.

On the other hand, the method for manufacturing the silicon substrate in accordance with the conventional technology has the following problems.

The high-cost and large-volume pulling apparatus is used for obtaining the plurality of silicon single-crystal wafers 8a, the silicon single-crystal 8 manufactured through the pulling apparatus is formed in only a round shape and the material cost is increased because there is generated a phenomenon that pieces of material are removed by the thickness of a wire of the cutter 9 in the cutting process to cut the silicon single-crystal 8.

Further, because a solar-cell substrate used to produce a solar cell is not round shape but square shape and the round-shaped silicon single-crystal wafers 8a should be cut in a square shape, the process becomes complicated and the yield is reduced. In addition, the solar-cell substrate should have a wide surface area to improve the efficiency thereof, however, because the silicon single-crystal wafers 8a by the conventional technology are cut by the cutting process and the surfaces thereof are flat and in case of using it as the solar cell substrate, an etching process to widen the surface area thereof should be performed additionally, whereby the process is complicated and the material cost is increased.

### SUMMARY OF THE INVENTION

It is an object of the present invention for solving the above-mentioned problems to provide a method for manufacturing a single-crystal substrate for obtaining a single-crystal silicon substrate from polycrystalline molten silicon by pouring the molten silicon into a square-shaped frame, solidifying the molten silicon and transferring a heating element from one corner of the frame to another corner opposite the corner and a method for manufacturing a solar cell using the single-crystal substrate produced by the method.

An object of the present invention can be achieved by providing a method for manufacturing a single-crystal substrate including the steps of: preparing a square-shaped frame; pouring polycrystalline molten silicon into the prepared frame; cooling and crystallizing the molten silicon; and forming the single-crystal silicon substrate by transferring a heating element from one corner of the frame to another corner opposite the corner, thus simplifying the entire manufacturing process of the single-crystal substrate.

At this time, the frame is made of a material having the higher melting point than the molten silicon and of tungsten or oxide.

Further, the heating element emits heat at higher temperature than the melting point of the molten silicon and is formed in a rod shape extended in a longitudinal direction. Particularly, the heating element is formed longer than a distance between the opposite corners of the frame and easily melts the single-crystal silicon formed by being solidified in the frame.

In addition, the object of the present invention can be achieved by providing a method for manufacturing a solar cell using the single-crystal substrate including the steps of: pouring polycrystalline molten silicon into a square-shaped frame; cooling and crystallizing the molten silicon; forming the single-crystal silicon substrate by transferring a heating element from one corner of the frame to another corner opposite the corner; forming a bottom electrode on the single-crystal silicon substrate; forming a PN junction layer on the bottom electrode; and forming a top electrode on the PN junction layer, thus simplifying the entire manufacturing process of the solar cell.

At this time, the frame is made of a material having the higher melting point than the molten silicon and made of tungsten or oxide having the higher melting point than the molten silicon.

Further, the heating element emits heat at higher temperature than the melting point of the molten silicon, is formed in a rod shape extended in a longitudinal direction and is formed longer than a distance between the opposite comers of the frame to facilitate melting the single-crystal silicon formed with being solidified in the frame.

Further, the bottom electrode is formed by using aluminum or silver and the top electrode is formed by using a transparent ITO(Indium-Tin Oxide) electrode.

Particularly, the method further includes a step of forming an antireflection coating on the top electrode to block the light reflected and discharged outside the solar cell, thus enhancing the power generation efficiency of the solar cell.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a cross-section view showing a single-crystal silicon pulling apparatus in accordance with a conventional technology;

FIG. 2 is a perspective view illustrating a cutting process of a single-crystal silicon in accordance with the conventional technology.

FIGS. 3 and 4 are perspective views illustrating a process for manufacturing a single-crystal substrate in accordance with the present invention;

FIG. 5 is a cross-section view showing a single-crystal substrate in accordance with the present invention; and

FIG. 6 to FIG. 8 are cross-section views illustrating a method for manufacturing a solar cell in accordance with the present invention.

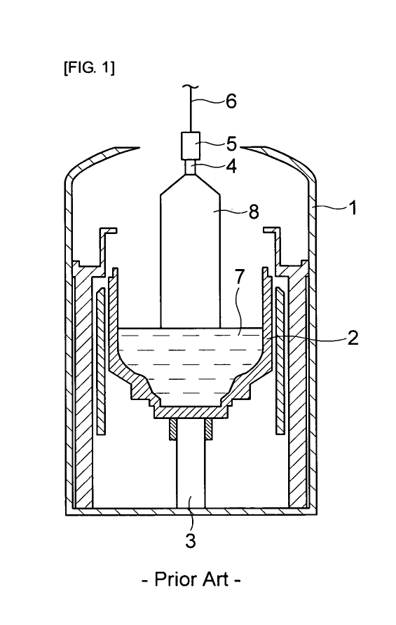

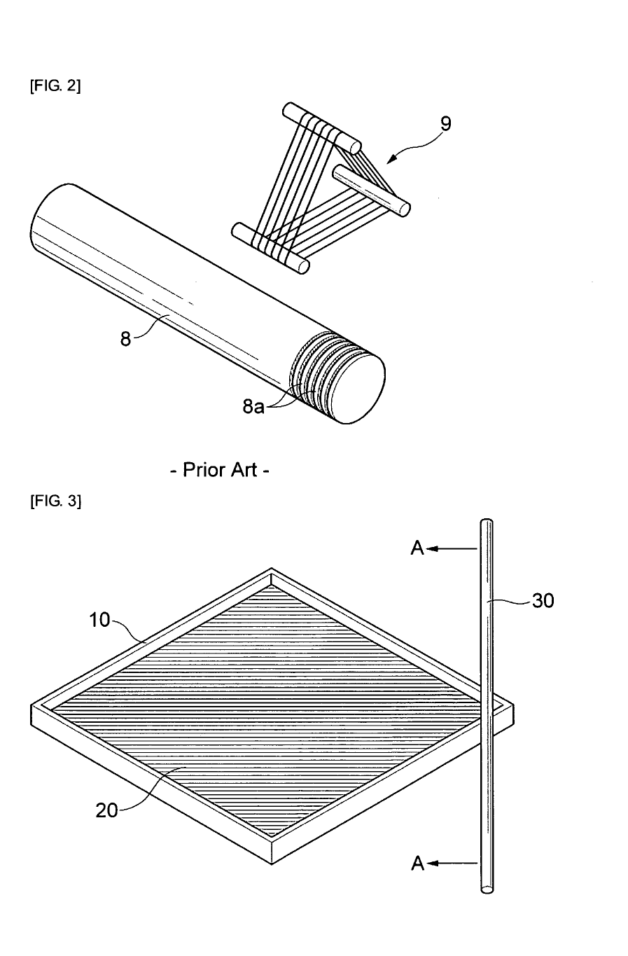

### DETAILED DESCRIPTION OF THE PREFERRED EMBODIMENTS

Hereinafter, a matter regarding to a method for manufacturing a single-crystal substrate, a method for manufacturing a solar cell using the same in accordance with the present invention and an effect thereof will be appreciated clearly through the following detailed description with reference to the accompanying drawings illustrating preferable embodiments of the present invention.

Method for Manufacturing a Single-Crystal Substrate

Hereinafter, a method for manufacturing a single-crystal substrate in accordance with the present invention will be described in detail with reference to the accompanying drawings.

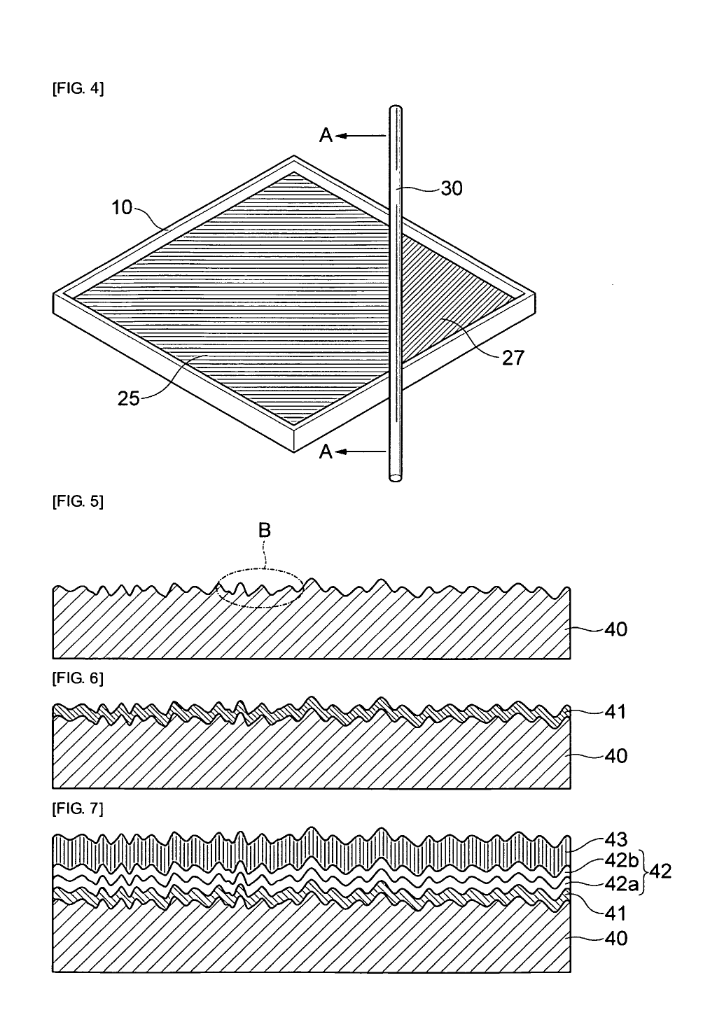

FIGS. 3 and 4 are perspective views illustrating a process for manufacturing a single-crystal substrate in accordance with the present invention and FIG. 5 is a cross-section view showing a single-crystal substrate in accordance with the present invention.

As shown in FIG. 3, in the method for manufacturing the single-crystal substrate in accordance with the present invention, first of all, polycrystalline molten silicon 20 is poured into a square-shaped frame 10.

At this time, it is preferable that the frame 10 is made of a material having higher melting point than the molten silicon 20 and maintains its shape as it is without being melted even when the molten silicon 20 is poured.

Particularly, it is preferable that the shape of the frame is not changed by the molten silicon 20 because the frame 10 is made of a material selected from a group consisting of tungsten, oxide, graphite or the like having higher melting point than the molten silicon 20.

As shown in FIG. 4, after the polycrystalline molten silicon 20 poured into the frame 10, thin-thickness polycrystalline silicon 25 is formed by solidifying the molten silicon 20 in the same square shape as the frame 10 with cooling the molten silicon for a predetermined time at room temperature.

At this time, the thickness of the polycrystalline silicon 25 is adjustable as the amount of the molten silicon 20 poured into the frame 10 and therefore it is possible to form the thin-thickness polycrystalline silicon 25.

As described above, when the molten silicon 20 is solidified, the crystal thereof has poly crystal and impurities contained in the molten silicon 20 is solidified as it is to form the low-purity polycrystalline silicon 25.

After the molten silicon 20 is solidified in the frame 10 entirely and the polycrystalline silicon 25 is formed, the heating element 30 is positioned at one corner of the frame 10. Then, the heating element 30 is gradually transferred in an ‘A’ direction from the corner where the heating element 30 is positioned to another corner opposite the corner.

At this time, the heating element 30 is made of the material capable of emitting heat at temperature at which the solidified molten silicon 20, that is, the polycrystalline silicon 25 is molten, positioned on the frame 10 to melt the polycrystalline silicon 25 positioned at a bottom part of the frame 10 and is formed longer than a distance between the opposite comers in a rod shape extended in a longitudinal direction to transmit heat all the regions of the frame 10.

That is, when the molten silicon 20 is solidified entirely and the molten silicon 20 in the frame 10 is formed to the polycrystalline silicon 25 as a whole, the heating element 30 is positioned at any one of comers of the frame 10. Then, when heating the heating element 30, the polycrystalline silicon 25 at the corner where the heating element 30 is positioned is molten by heat radiated from the heating element 30.

In such a state, when gradually transferring the heating element 30 in the “A” direction, while the polycrystalline silicon 25 at the corner is molten and solidified again, a single-crystal silicon 27 is formed and impurities contained in the polycrystalline silicon 25 is pushed toward a region where the heating element 30 is positioned and molten.

When the heating element 30 is transferred continuously in the “A” direction, the polycrystalline silicon 25 which is molten by the heating element 30 and solidified again is solidified to single crystal as a whole by being influenced by the single crystal of the corner and the impurities are pushed out, thereby obtaining a thin single crystal substrate 40 made of single crystals as shown in FIG. 5. And, at the same time, there is an advantage in which because the single silicon 27 does not contain the impurities, the purity is enhanced.

Particularly, because the single-crystal substrate 40 made in accordance with the present invention is formed while the polycrystalline silicon 25 is melted and solidified again, the top part thereof is not flat and is formed in a rugged shape as the shown ‘B’.

Accordingly, in the case where the solar cell is produced using the single-crystal substrate 40, an etching process on a top surface of a bottom substrate is not required to enlarge the surface area of the bottom substrate to simplify the entire process.

Further, because the thickness of the single-crystal substrate 40 is adjustable by adjusting only the amount of the molten silicon 20 poured into the frame 10, it is possible to produce the thin-thickness single-crystal substrate 40, thereby reducing the size of a device adopting the single-crystal substrate 40.

In addition, there is another advantage in that it is possible to simplify the entire process for manufacturing the single-crystal substrate 40 by forming the single-crystal substrate 40 using the heating element 30 after pouring the molten silicon 20 into the square-shaped frame 10 not producing the single-crystal substrate through the large-volume pulling apparatus as the conventional technology.

Method for Manufacturing a Solar Cell using the Single-Crystal Substrate

Hereinafter, a method for manufacturing a solar cell using a single-crystal substrate in accordance with the present invention will be described in detail with reference to the accompanying drawings.

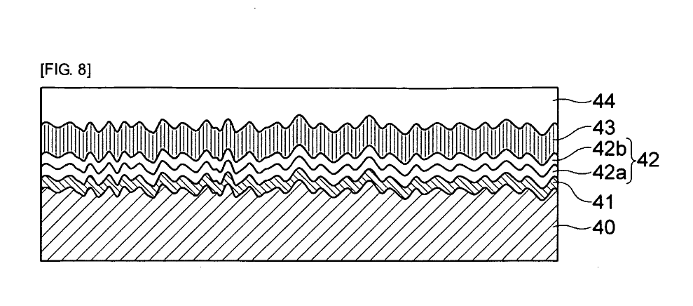

FIG. 6 to FIG. 8 are cross-section views illustrating a method for manufacturing a solar cell in accordance with the present invention.

First of all, a thin-thickness single-crystal substrate 40 is made by the above-mentioned method for manufacturing the single-crystal substrate in accordance with the present invention.

Then, a bottom electrode 41 is formed onto the single-crystal substrate 40. At this time, the bottom electrode 41 is formed by using a transparent conductive material and an ITO(Indium-Tin Oxide) electrode is used as the transparent conductive material.

After forming the bottom electrode 41 onto the single-crystal substrate 40, an N-type silicon layer 42a is formed onto the bottom electrode 41. The N-type silicon layer 42a is doped by N-type impurities such as phosphorous or nitrogen.

Further, a P-type silicon layer 42b is formed onto the N-type silicon layer 42a and the P-type silicon layer 42b is doped by P-type impurities as a Group 3 element such as boron. The thus-formed N-type and P-type silicon layers 42a and 42b constitutes a PN junction layer 42 and the PN junction layer 42 may be formed through a plasma CVD(Plasma Chemical Vapor Deposition) process or an inductively coupled plasma CVD process.

In the thus-formed PN junction layer 42, there are generated electrons and holes by interaction with the light impinged from the outside, and the generated electrons are diffused into the N-type silicon layer 42a and the holes are diffused into the P-type silicon layer 42b respectively. At this time, when electrically connecting the N-type silicon layer 42a and the P-type silicon layer 42b, desired power is generated by the movement of the electrons and the holes.

Particularly, the surface area of the single-crystal substrate 40 becomes wider than the surface area in case of the flat surface of the conventional wafer by a rugged shape like the ‘B’ and the region where the electron and the holes are formed becomes wider, thereby generating more power to enhance power efficiency.

Further, because a top surface of the single-crystal substrate 40 itself is formed rugged like the ‘B’, an additional etching process among conventional processes for manufacturing a solar cell is not required to form a rugged shape, thus shorten the manufacturing processes.

After forming the thus-formed PN junction layer 42 on the bottom electrode 41, a top electrode 43 made of a conductive material is formed onto the PN junction layer 42. At this time, the top electrode 43 is formed by using a transparent electrode such that the light impinged from the outside passes through the PN junction layer 42 and it is preferable to form the top electrode 43 using the ITO electrode as a transparent conductive electrode like the bottom electrode 43. At this time, a method for forming the top electrode 43 uses any one of a spattering process or a vapor deposition process.

On the other hand, as shown in FIG. 8, on the top electrode 43, there may be further formed an antireflection coating 44 to prevent the light impinged from the outside from being reflected and discharged outside by the bottom electrode 41. At this time, the antireflection coating 44 has an advantage in that the antireflection coating blocks the light reflected and discharged outside by the bottom electrode 41 and thus improves the power generation efficiency of the solar cell.

The above-described method for manufacturing the solar cell using the single-crystal substrate 40 has an effect to reduce the manufacturing processes, after pouring the polycrystalline molten silicon 10 into the square-shaped frame 10, by transferring the heating element 30 and forming the single-crystal silicon B simply in comparison with the case that the single-crystal wafers 8a obtain the flat surfaces through cutting of the single-crystal silicon 8, wherein the conventional seed crystal forms the single crystal.

Further, in the method for manufacturing the solar cell in accordance with, the top part of the single-crystal substrate 40 is formed in a rugged shape and an additional etching process to widen the surface area is not required, thereby reducing the manufacturing processes and it is possible to determine the thickness of the single-crystal substrate 40 based on the amount of the molten silicon 20, thus producing the thin-thickness single-crystal substrate 40.

As described above, in the method for manufacturing the single-crystal substrate and the method for manufacturing the solar cell using it, there is an advantage in that the manufacturing processes are reduced by pouring the molten silicon into the square-shaped frame, solidifying the molten silicon and transferring the heating element from one corner of the frame to another corner opposite the corner, thus obtaining the single-crystal silicon substrate from the polycrystalline molten silicon and the material cost is reduced because the large-volume pulling apparatus is not used and the cutting process is not required.

Further, the present invention has another advantage in that the purity is improved by transferring the impurities contained in the molten silicon to any one corner in a single-crystallizing process and the processes are simplified because the surface is formed rugged and an additional etching process is not required.

As described above, although a few preferable embodiments of the present invention have been shown and described, it will be appreciated by those skilled in the art that substitutions, modifications and changes may be made in these embodiments without departing from the principles and spirit of the general inventive concept, the scope of which is defined in the appended claims and their equivalents.

What is claimed is:

1. A method for manufacturing a single-crystal substrate comprising the steps of:
preparing a square-shaped frame;
pouring polycrystalline molten silicon into the prepared frame;
cooling and crystallizing the molten silicon; and
forming the single-crystal silicon substrate by transferring a heating element from one corner of the frame to another corner opposite the corner.

2. The method according to claim 1, wherein the frame is made of a material including the higher melting point than the molten silicon.

3. The method according to claim 2, wherein the frame is made of a material selected from a group consisting of tungsten, oxide, graphite or the like.

4. The method according to claim 1, wherein the heating element emits heat at higher temperature than the melting point of the molten silicon.

5. The method according to claim 4, wherein the heating element is formed in a rod shape extended in a longitudinal direction.

6. The method according to claim 5, wherein the heating element is formed longer than a distance between the opposite comers of the frame.

7. A method for manufacturing a solar cell comprising the steps of:
pouring polycrystalline molten silicon into a square-shaped frame;
cooling and crystallizing the molten silicon;
forming a single-crystal silicon substrate by transferring a heating element from one corner of the frame to another corner opposite the corner;
forming a bottom electrode on the single-crystal silicon substrate;
forming a PN junction layer on the bottom electrode; and
forming a top electrode on the PN junction layer.

8. The method according to claim 7, wherein the frame is made of a material including the higher melting point than the molten silicon.

9. The method according to claim 8, wherein the frame is made of a material selected from a group consisting of tungsten, oxide, graphite, or the like.

10. The method according to claim 7,.wherein the heating element emits heat at higher temperature than the melting point of the molten silicon.

11. The method according to claim 10, wherein the heating element is formed in a rod shape extended in a longitudinal direction.

12. The method according to claim 5, wherein the heating element is formed longer than a distance between the opposite corners of the frame.

13. The method according to claim 7, wherein the bottom electrode is formed by using aluminum or silver.

14. The method according to claim 7, wherein the top electrode is formed by using a transparent ITO(Indium-Tin Oxide) electrode.

15. The method according to claim 7, further comprising a step of forming an antireflection coating on the top electrode.
